(19) United States
(12) Patent Application Publication
(10) Pub. No.: US 2014/0342193 A1
(43) Pub. Date: Nov. 20, 2014

(54) SMART BATTERY SYSTEM

(71) Applicant: Tenergy Corporation, Fremont, CA (US)

(72) Inventors: Benjamin C. MULL, San Jose, CA (US); Lon SCHNEIDER, Fremont, CA (US); Gurudev KARANTH, San Carlos, CA (US)

(73) Assignee: TENERGY CORPORATION, Fremont, CA (US)

(21) Appl. No.: 13/896,985

(22) Filed: May 17, 2013

(51) Int. Cl. H01M 10/42; G01R 31/36

(52) U.S. Cl. CPC H01M 10/4257; G01R 31/3606
USPC 429/50; 320/134; 429/61

(57) ABSTRACT

Apparatus, systems, and methods for monitoring one or more batteries are disclosed. One such apparatus may include a battery management device. The battery management device may include a sensor configured to detect a characteristic of a battery, a processor communicatively connected with the sensor to receive a signal indicative of the characteristic of the battery, a network interface to send the signal to a server through a network and to receive an instruction from the server through the network, and a control circuit to control one or more aspects of the battery based on the received instruction.

### FIELD OF THE DISCLOSURE

The present disclosure relates to apparatus, systems, and methods for managing batteries. More particularly, the present disclosure relates to apparatus, systems, and methods for managing batteries that are connected to a network.

### BACKGROUND OF THE DISCLOSURE

A battery is typically considered as an energy source to provide electrical energy to electronic or power devices. For example, rechargeable batteries used in cellphones and laptop computers are normally separate functional components from the main electronics control system. The interface between a battery and its energy-consuming device typically has only limited functionalities. In addition, information about battery status is often limited to certain basic properties, and is often confined to be available to and used by only the associated energy-consuming device for the purpose of local operation and protection. Thus, it is difficult to effectively manage batteries under such traditional battery utilization framework.

Therefore, it is desirable to develop smart battery systems and corresponding methods to improve the efficiency of managing batteries and expand the functionality thereof.

### SUMMARY OF THE EMBODIMENTS

The present application provides apparatus, systems, and methods for managing batteries. Some disclosed embodiments may involve a battery management device. The battery management device may include a sensor configured to detect a characteristic of a battery, a processor communicatively connected with the sensor to receive a signal indicative of the characteristic of the battery, a network interface to send the signal to a server through a network and to receive an instruction from the server through the network, and a control circuit to control one or more aspects of the battery based on the received instruction. The characteristics of a battery that can be monitored may include electrical properties, such as voltage, current, impedance, charge, etc.; mechanical properties, such as displacement, acceleration, strain, tension, location, etc.; chemical properties, such as gas (e.g., CO, CO₂) emission; or other properties such as internal or external temperature, humidity, etc. The one or more aspects to be controlled may include thresholds of these characteristics or other parameters related to these characteristics (e.g., time, etc.).

The present application also provides a battery management system. According to some embodiments, the battery management system may include a battery and a controller coupled to the battery. The controller may include a sensor configured to detect a characteristic of a battery, a processor communicatively connected with the sensor to receive a signal indicative of the characteristic of the battery, a network interface to send the signal to a server through a network and to receive an instruction from the server through the network, and a control circuit to control one or more aspects of the battery based on the received instruction.

The present application also provides a method for managing a battery. According to some embodiments, the method may include detecting a characteristic of the battery, generating a signal indicative of the characteristic of the battery, sending the signal to a server through a network, receiving an instruction from the server through the network, and controlling one or more aspects of the battery based on the received instruction.

The preceding summary is not intended to restrict in any way the scope of the claimed invention. In addition, it is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate various embodiments and exemplary aspects of the present invention and, together with the description, explain principles of the invention. In the drawings:

FIG. 1A is a schematic diagram of an exemplary smart battery system, in accordance with some disclosed embodiments;

FIG. 1B is a schematic diagram of another exemplary smart battery system, in accordance with some disclosed embodiments;

FIG. 2 is a schematic diagram of an exemplary smart battery assembly, in accordance with some disclosed embodiments;

FIG. 3 is a schematic diagram of an exemplary monitoring module of a smart battery controller, in accordance with some disclosed embodiments;

FIG. 4 is a schematic diagram of some exemplary controlling units of a smart battery controller, in accordance with some disclosed embodiments;

FIG. 5 is a schematic diagram of an exemplary server of a smart battery system, in accordance with some disclosed embodiments;

FIG. 6 is an exemplary configuration of a smart battery cloud, in accordance with some disclosed embodiments; and

FIG. 7 is a flow chart of an exemplary method for performing smart battery management, in accordance with some disclosed embodiments.

### DETAILED DESCRIPTION OF THE EMBODIMENTS

Reference will now be made in detail to exemplary embodiments of the invention, examples of which are illustrated in the accompanying drawings. When appropriate, the same reference numbers are used throughout the drawings to refer to the same or like parts.

Embodiments of the present disclosure may involve apparatus, systems, and methods for managing batteries. As used herein, batteries may include any device comprising one or more electrochemical cells that convert stored chemical energy into electrical energy, such as zinc-carbon batteries, alkaline batteries, lead-acid batteries, nickel-cadmium batteries, nickel-zinc batteries, nickel metal hydride batteries, lithium-ion batteries, etc. The batteries may be used in electronics, computers, medical devices, power tools, cars, etc. The batteries may form a battery pack, including multiple battery cells connected in series, in parallel, or having both series and parallel configurations. In this disclosure, the term battery may refer to a battery pack including multiple cells or a single battery cell. Managing the battery may include monitoring battery status, setting thresholds/parameters, and controlling battery behavior. The status and/or characteristics of a battery that can be monitored may include its electrical properties, such as voltage, current, impedance, charge, etc.; mechanical properties, such as displacement, acceleration, strain, tension, location, etc.; chemical properties, such as gas (e.g., CO, CO₂) emission; or other properties such as internal or external temperature, etc. The apparatus, systems, and methods for managing batteries can also monitor properties of the environment where the batteries operate. Such properties include temperature, humidity, etc. The behaviors and/or parameters of a battery that can be controlled may include voltage, current, stored charges, thresholds, on/off switching, charging/discharging switching, etc.

Information regarding battery status may be transmitted to a server through a network. The server may store and analyze such information and issue instructions to control one or more aspects of a battery. The instructions may be transferred to the battery through the network. The server may collect battery information from a plurality of batteries. The plurality of batteries may reside in the same location or may reside in different locations. The plurality of batteries may be of similar types or different types. The information regarding the plurality of batteries may be stored and/or analyzed by the server. The server may utilize the information to manage one or more of the plurality of the batteries, or other batteries connected to the server. The server and/or the individual battery may provide interfaces for local and/or remote users to access the battery status information and/or to control one or more aspects of a battery. Third party service providers may also connect to the network to provide value-added services.

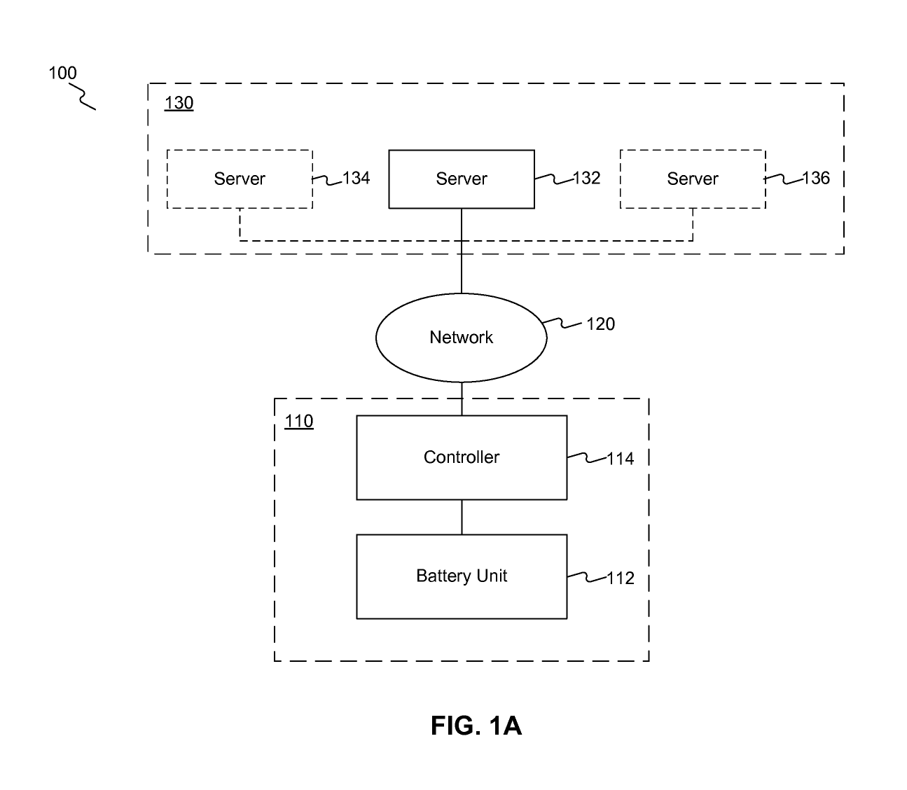

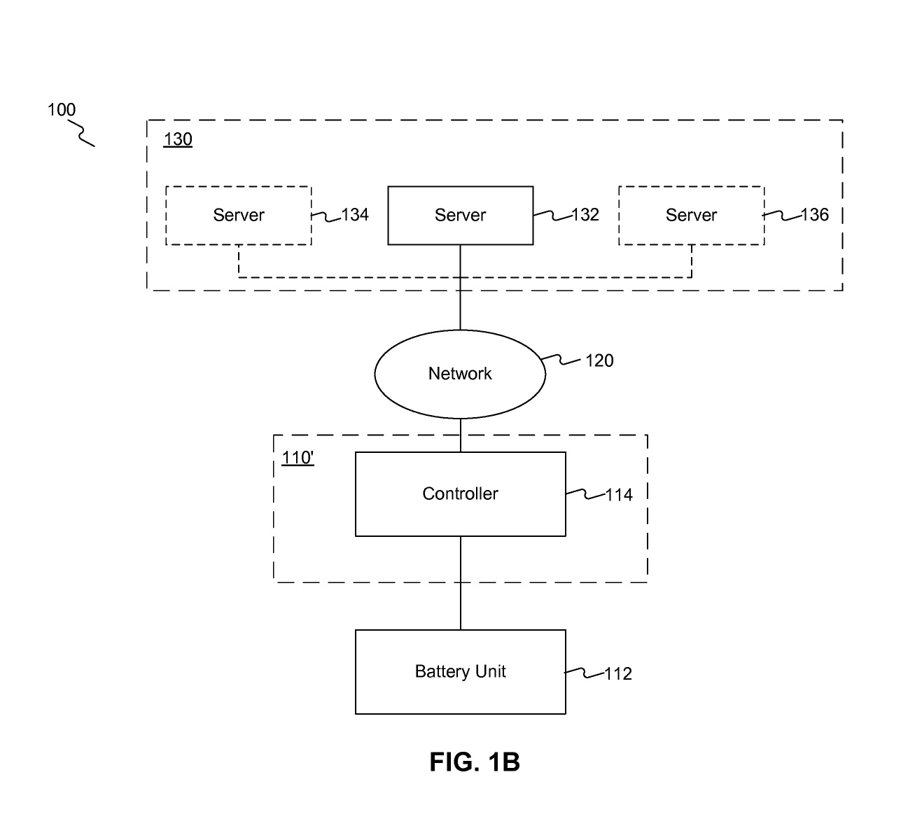

FIG. 1A is a schematic diagram of an exemplary smart battery system 100, in accordance with some disclosed embodiments. As used herein, a smart battery system refers to a system including not only one or more batteries as energy sources, but also information flows about the batteries. In other words, a smart battery system includes an integration of energy and information.

Referring to FIG. 1A, smart battery system 100 may include a battery assembly 110, a network 120, and a cloud 130. Battery assembly 110 may include a battery unit 112 and a controller 114. In some embodiments, controller 114 may be integrated into battery unit 112 with other controlling circuits. For example, controller 114 may be directly integrated into a PCB that is physically embedded into battery unit 112. In another example, controller 114 may include one or more ICs that are soldered, plugged, or otherwise electrically connected to the PCB. In other embodiments, controller 114 may be a separate device from battery unit 112 and can be communicatively connected with battery unit 112. For example, controller 114 may include one or more modular circuit boards and/or IC chips that are removably connected to battery unit 112. In another example, controller 114 may be connected with battery unit 112 by wires or other means that can provide information exchange with battery unit 112. In some other embodiments, controller 114 may be included in a battery charger, so that controller 114 may monitor battery conditions when the battery is connected to the charger and control the charging process of the battery. For example, in the exemplary system shown in FIG. 1B, controller 114 may be included in a battery charger or a device (e.g., a cell phone) 110′. Battery unit 112 may be connected to battery charger or a device (e.g., a cell phone) 110′. Controller 114 may monitor conditions of battery unit 112 and control various aspects of battery unit 112 during charging, discharging, and/or other relevant processes of battery unit 112.

In some embodiments, one or more monitoring units and/or controlling units may be provided on battery unit 112 and controller 114 may communicate with the monitoring/controlling units through one or more information exchange links. In other embodiments, one or more monitoring units and/or controlling units may be provided on controller 114 and the monitoring/controlling units may monitor/control one or more characteristics of battery unit 112.

Cloud 130 may include one or more servers. For example, as shown in FIG. 1A, cloud 130 may include a server 132. In some embodiments, cloud 130 may include additional servers, such as servers 134 and 136 shown in dashed lines. The number of servers used in cloud 130 may depend on particular applications. For examples, one, two, three, or more servers may be used. Servers in cloud 130 may be substantially the same as one another or may be different. For example, in a data center, a group of similar server computers may form a cluster to provide computation service. In another example, server computers differing in brand, size, operating system, computational power, location, etc. may be communicatively connected with one another to form a distributed computational environment. It is noted that the above description is merely exemplary, and the scope of the present invention is not limited by the special examples provided above. Modifications and variations in the implementation of cloud 130 are within the scope of the present invention so long as the functional goal of network connected computation is achieved.

Cloud 130 (e.g., server 132 or additionally servers 134 and 136) and battery assembly 110 (e.g., through controller 114) may communicate with each other through a network 120. Cloud 130 may receive information from battery assembly 110 via network 120 and store the information on the cloud (e.g., on server 132). In addition, cloud 130 may send information to battery assembly 110 via network 120. Therefore, the information flow between cloud 130 and battery assembly 110 may be bidirectional. Network 120 may include LAN, WAN, VPN, Internet, telecommunication network, Bluetooth, NFC, etc.

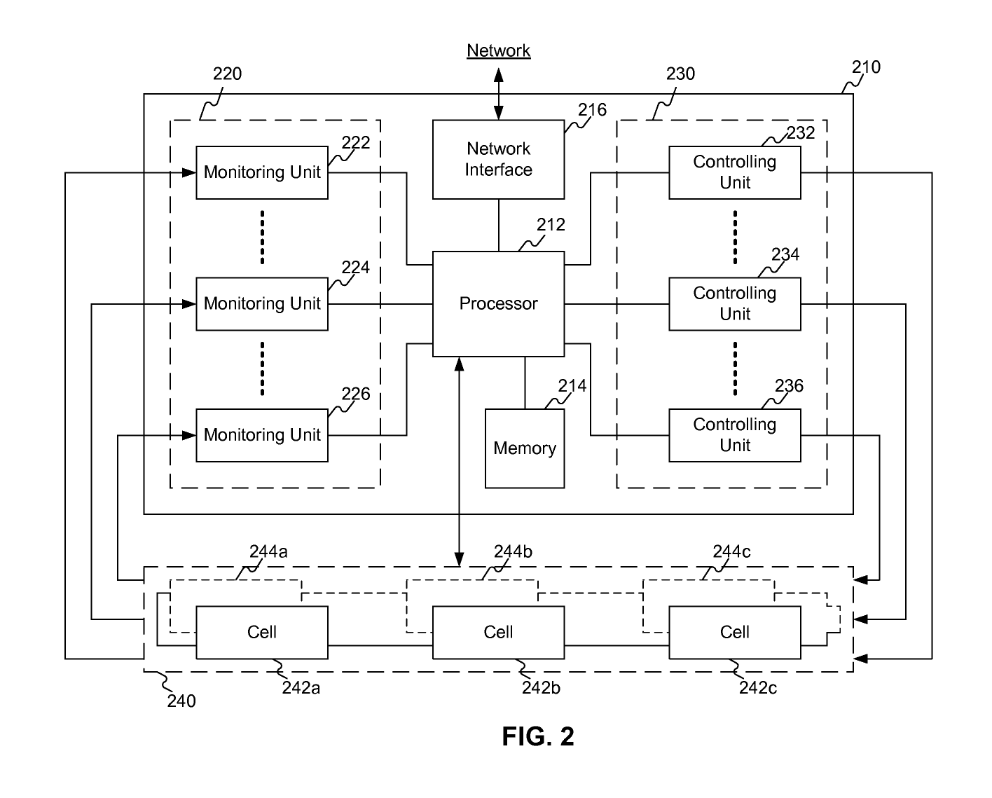

FIG. 2 is a schematic diagram of an exemplary smart battery assembly, in accordance with some disclosed embodiments. In FIG. 2, controller 210 is an exemplary implementation of controller 114 and battery 240 is an exemplary implementation of battery unit 112. Controller 210 may include a processor 212. Processor 212 may include a central processing unit (“CPU”), a graphic processing unit (“CPU”), digital signal processor (“DSP”), field-programmable gate array (“FPGA”), and/or other suitable information processing devices. Depending on the type of hardware being used, processor 212 may include one or more printed circuit boards, and/or one or more microprocessor chips. Processor 212 can execute sequences of computer program instructions to perform various tasks. For example, processor 212 may execute battery-monitoring software instructions to monitor the status and various properties of battery 240. Processor 212 can process one or more signals generated by one or more monitoring units and communicate with cloud 130 through, for example, a network interface 216. In another example, processor 212 can execute battery-controlling software instructions to control one or more aspects of battery 240. In another example, processor 212 can execute indirect battery-controlling software instructions to control one or more aspects of a battery charger or a battery-using device either directly or through cloud 130. The control instructions may be generated by processor 212 or received from cloud 130 through network interface 216.

Controller 210 may include a memory 214. Memory 214 may include, among other things, a random access memory (“RAM”) and/or a read-only memory (“ROM”). Computer program instructions and/or digital data can be stored, accessed, and read from memory 214 for execution by processor 212. For example, memory 214 may store one or more software applications. Further, memory 214 may store an entire software application or only part of a software application that is executable by processor 212. It is noted that although only one block is shown in FIG. 2, memory 214 may include multiple physical devices.

Network interface 216 may provide wired or wireless communication connections to network 120. For example, network interface 216 may include Ethernet, WiFi, Bluetooth, NFC, telecommunication connection (3G, 4G, LTE, etc.), or other suitable communication devices. Network interface 216 may provide network connection using TCP/IP, HTTP, HTTPS, UDP, or other suitable protocols. In some embodiments, an application programming interface (API) may be provided to facilitate communication between controller 210 and cloud 130.

Battery 240 may include one or more cells connected with one another in series and/or parallel. For example, FIG. 2 shows an exemplary configuration in which two groups of cells are connected in parallel and cells in each group are connected in series. Referring to FIG. 2, cells 242a, 242b, and 242c are connected in series to form the first group, and cells 244a, 244b, and 244c are connected in series to form the second group. The two groups are connected in parallel to provide energy as a whole. It is noted that other configurations can be used. For example, one embodiment may only include series-connected cells (e.g., the cells in dashed-lines can be omitted). Another embodiment may only include parallel-connected cells. Yet another embodiment may include a combination of series- and parallel-connected cells. The number of cells may vary depending on particular applications. For example, one, two, three, or more cells may be used to form a series- or parallel-connected cell group.

In some embodiments, processor 212 may communicate directly with battery 240, as indicated by the double-headed arrow between processor 212 and battery 240. The communication may be carried out in analog and/or digital form. For example, processor 212 may include an analog port that can input/output analog signals (e.g., voltage signals or current signals). The analog port may be electrically connected to certain part of battery 240 to directly read/write analog signals. In another example, processor 212 may include a digital port that can input/output digital signals. The digital port may be electrically connected to certain digital terminal of battery 240 to directly read/write digital signals. Information can be communicated directly, wirelessly or through the cloud between processor 212 and battery 240 or to a charger or a battery-connected device. This information may include, for example, battery identification information (e.g., brand, model, serial number, etc.), timing information (e.g., date, time, running duration), cell configuration (series/parallel/combination configuration), and charging or discharging parameters, etc.

Processor 212 may communicate with battery 240 through intermediate devices. The intermediate devices include, among others, monitoring module 220 and controlling module 230. Monitoring module 220 may include one or more monitoring units to monitor the status of battery 240. Controlling module 230 may include one or more controlling units to control the behavior of battery 240. For example, in FIG. 2, monitoring module 220 includes three monitoring units 222, 224, and 226. Each monitoring unit may communicate with battery 240 to monitor one or more aspects of battery 240. Similarly, controlling module 230 includes three controlling units 232, 234, and 236. Each controlling unit may communicate with battery 240 to control one or more aspects of battery 240. The number of monitoring/controlling units may vary, depending on particular applications. In some embodiments, processor 212 may communicate with one or more monitoring/controlling units via I²C bus, SMBus, or wirelessly.

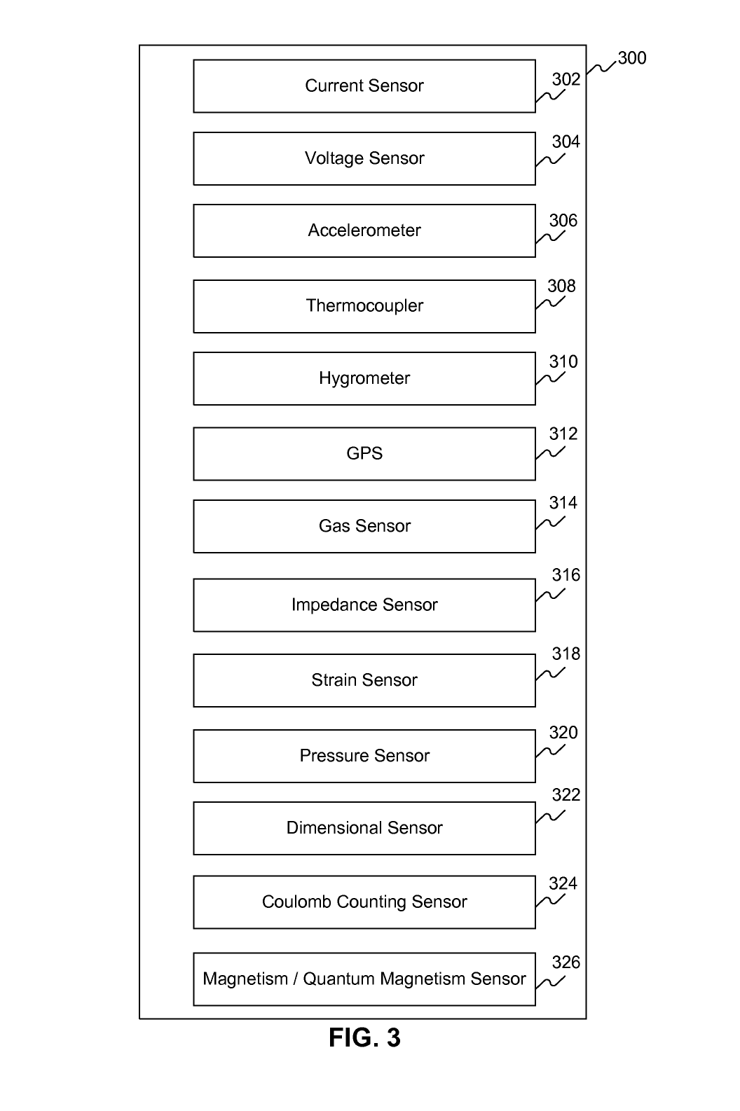

FIG. 3 is a schematic diagram of an exemplary monitoring module 300 of a smart battery controller, in accordance with some disclosed embodiments. As described above, a monitoring module may include one or more monitoring units to monitor one or more aspects of a battery. Monitoring module 300 shown in FIG. 3 provides an exemplary implementation of such monitoring module. Referring to FIG. 3, monitoring module 300 includes a current sensor 302, a voltage sensor 304, a accelerometer 306, a thermocoupler 308, a hygrometer 310, a GPS 312, a gas sensor 314, an impedance sensor 316, a strain sensor 318, a pressure sensor 320, and a dimensional sensor 322. It is noted that the list of monitoring units shown in FIG. 3 is not an exhaustive list. Additional monitoring units may be included. On the other hand, one or more monitoring units shown in FIG. 3 may be omitted.

Current sensor 302 may detect/monitor the current value of battery 240 or its individual cells during charging and/or discharging process. The current value may be detected directly or indirectly. In some embodiments, a current sensing device may be mounted on a PCB and be connected in series with one or more battery cells, such as directly coupled to one terminal of a battery cell, to measure input/output current to/from the cell(s) directly. The measured current value may be converted into a voltage value and read by or provided to processor 212 in analog or digital form. In other embodiments, voltage values across one or more cells may be measured and corresponding current value flowing through the cell(s) may be derived from the measured voltage values. The calculation of current value can be accomplished by either current sensor 302 or processor 212. The derived current value (e.g., after calculation) or measured voltage values (e.g., before calculation) may be read by processor 212 in analog or digital form. Processor 212 may store the current value locally, e.g., in memory 214. Alternatively or additionally, processor 212 may send the current value to cloud 130 through network 120.

Voltage sensor 304 may detect/monitor the voltage level of battery 240 or its individual cells. For example, voltage values (e.g., with respect to ground or floating) may be measured at one or more points of the battery cell circuit and read by or provided to processor 212 in analog or digital form. Voltage sensor 304 may be coupled to two terminals of battery 240, or an individual battery cell. Voltage sensor 304 may be mounted on the PCB where the current sensor 302 is installed. Voltage drops across one or more cells may be obtained from the measured voltage values. Similar to the current values, voltage values may be stored locally and/or sent to cloud 130.

In some embodiments, both current values and voltage values may be measured using only one sensor (e.g., voltage sensor or current sensor). For example, either current or voltage value may be measured directly, while the other value may be derived from the measured value. Therefore, instead of using two sensors, only one sensor may be used.

Accelerometer 308 may detect and/or monitor acceleration (e.g., acceleration associated with the phenomenon of weight) experienced by battery 240. For example, the acceleration of battery 240 at rest on the surface of the earth may be g=9.81 m/s² straight upwards, due to its weight. In another example, the acceleration of battery 240 in free fall may be zero. Accelerometer 308 may include single- and/or multi-axis models to detect magnitude and/or direction of the proper acceleration (or g-force), as a vector quantity, of battery 240. Accelerometer 308 can be used to sense orientation (e.g., because direction of weight changes), coordinate acceleration (e.g., when it produces g-force or a change in g-force), vibration, shock, and falling of battery 240, among others. Accelerometer 308 may be directly coupled to battery 240 so that it can measure accurately the acceleration of battery 240, and the measurement will not be interfered by any intermediate component that may serve as a cushion.

Thermocoupler 308 may measure the temperature of battery 240 or one or more parts of battery 240. The system may use one or more thermocouplers to measure temperature at different locations, for example, an internal thermocoupler for measuring the temperature inside a battery cell, and an external thermocoupler for measuring the ambient temperature. The system may also include more thermocouplers, for example, a thermocoupler for each of the individual cells, one for the center region of battery pack 240, the peripheral region of battery 240, etc.

Hygrometer 310 may measure the humidity in the environment in which battery 240 resides. For example, hygrometer 310 may measure the moisture content in the environment and derive or calculate the humidity level. Hygrometer 310 may include metal-paper coil hygrometers, hair tension hygrometers, chilled mirror dewpoint hygrometers, capacitive humidity sensors, resistive humidity sensors, thermal conductivity humidity sensors, etc. Hygrometer 310 may be mounted on the PCB that includes current sensor 302 and/or voltage sensor 304. The humidity level may impact battery/electronics performance.

GPS receiver 312 may provide the geographical location of battery 240. Battery control may be adapted and/or optimized based on the geographical location. For example, charging/discharging parameters/thresholds or schemes for a battery located in a low latitude region may be different from that for a battery located in a high latitude region. In another example, battery health standard may be different at high altitude from that at sea level.

Through GPS receiver 312, a user may know the location of battery 240, and set charging/discharging parameters/thresholds or schemes, and/or other parameters, such as threshold of humidity, temperature, pressure, gas level, etc. For example, if the user detect that battery 240 is at a location that is normally hot, the user may set the maximum current for battery 240 to be certain amount to prevent battery 240 from being over-heated. The system may include a current limiting circuit or a circuit breaker. When the current reaches the maximum current, the system may activate the current limiting circuit or the circuit breaker to reduce the current or break the circuit.

GPS receiver 312 can receive radio signals from GPS satellites. GPS receiver 312 can calculate the location based on the received radio signals. Alternatively, processor 212, which is coupled to GPS receiver 312, can receive signals from GPS receiver 312, and calculate the location or send the signals to remote server 132 for calculation.

Gas sensor 314 may detect the presence and/or the concentration level of certain gaseous molecules, such as carbon monoxide (CO) and/or carbon dioxide (CO₂), emitted by battery 240. Battery 240 may emit these gaseous molecules in certain circumstances, such as overheat, over/under charged, dead/damaged cell(s), etc. The presence of such gaseous molecules may indicate that battery 240 is compromised or damaged. The concentration level of the gaseous molecules may indicate the degree of damage and/or the duration of the damage. Gas sensor 314 may include opto-chemical sensors, biomimetic sensors, electrochemical sensors, and/or semiconductor sensors, among others. The system may include gas sensor 314 placed inside a battery cell and/or close to a battery cell.

Impedance sensor 316 may detect/monitor the internal impedance (e.g., resistance) of battery 240 or its individual cells. The internal impedance may provide indications of battery health status (e.g., aging and/or potential damage). Impedance sensor 316 may be connected in series with a battery cell.

Strain sensor 318 (also known as a strain gauge) may measure the strain experienced by battery 240 (or a battery cell). The strain may provide indications of potential physical damage and/or deformation of battery due to physical impact or internal gassing. Strain sensor 318 may include an insulating flexible backing which supports a metallic foil pattern. Strain sensor 318 may be attached to battery 240 by a suitable adhesive, such as cyanoacrylate. As battery 240 deforms, the foil deforms correspondingly, causing its electrical resistance to change. The resistance change, which may be measured using a Wheatstone bridge, corresponds to the strain (e.g., by a quantity known as the gauge factor) experienced by battery 240. Therefore, by detecting the resistance change, the strain of battery 240 may be measured.

Pressure sensor 320 (also known as a pressure gauge) may measure the pressure experienced by battery 240. Pressure increase due to internal gassing may indicate potential cell damage/fail. Pressure sensor 320 may be placed inside a battery cell. Pressure sensor 320 can be implemented by a conventional pressure sensor, such as a piezoresistive strain gauge, a capacitive pressure sensor, an electromagnetic pressure sensor, or an optical pressure sensor. For example, a capacitive sensor may use a diaphragm and pressure cavity to create a variable capacitor to detect applied pressure. The diaphragm can be a metal, ceramic, and silicon diaphragm. When the pressure changes, the capacitance of the capacitor changes and such changes can be detected.

Dimensional sensor 322 may measure the dimension and/or dimension variation of battery 240. Dimension change due to internal gassing may indicate potential cell damage/fail. Dimension sensor 322 may be directly coupled to an external surface of a battery cell.

Coulomb counting sensor 324 may measure the coulombs into or out of the battery 240. Coulomb counting may be used to determine state of charge of the battery.

Magnetism/Quantum Magnetism sensor 326 may measure the magnetic state of the battery 240. Magnetism/Quantum Magnetism measurement may be used to improve charge methods and diagnose battery deficiencies, including predicting end-of-life by measuring battery capacity.

FIG. 3 shows that all the sensors are in one module 300. A person having ordinary skill should appreciate that this is just for convenience of illustration. The sensors may be placed at different locations, and may not be connected with each other. In addition, in the above description, the sensors have been described in connection with battery 240. A person having ordinary skill in the art should appreciate that the sensors can be used to monitor a battery pack, or an individual battery cell. In this disclosure, battery 240 can be a battery pack, or a battery cell.

Processor 212 may perform PCB self-diagnosis to detect if one or more components (e.g., monitoring/controlling units) on the PCB control board function properly. The self-diagnostic information may provide indications of battery health status. For example, certain component may fail when the battery emits gas, the pressure inside the battery increases, the battery undergoes deformation or physical damage, etc.

The communication of monitoring information between controller 210 and cloud 130 may be instantaneous, periodical, or event driven. In some embodiments, raw data obtained from one or more monitoring units may be transmitted to cloud 130. In other embodiments, raw data may be pre-processed by processor 212 before being transmitted to cloud 130.

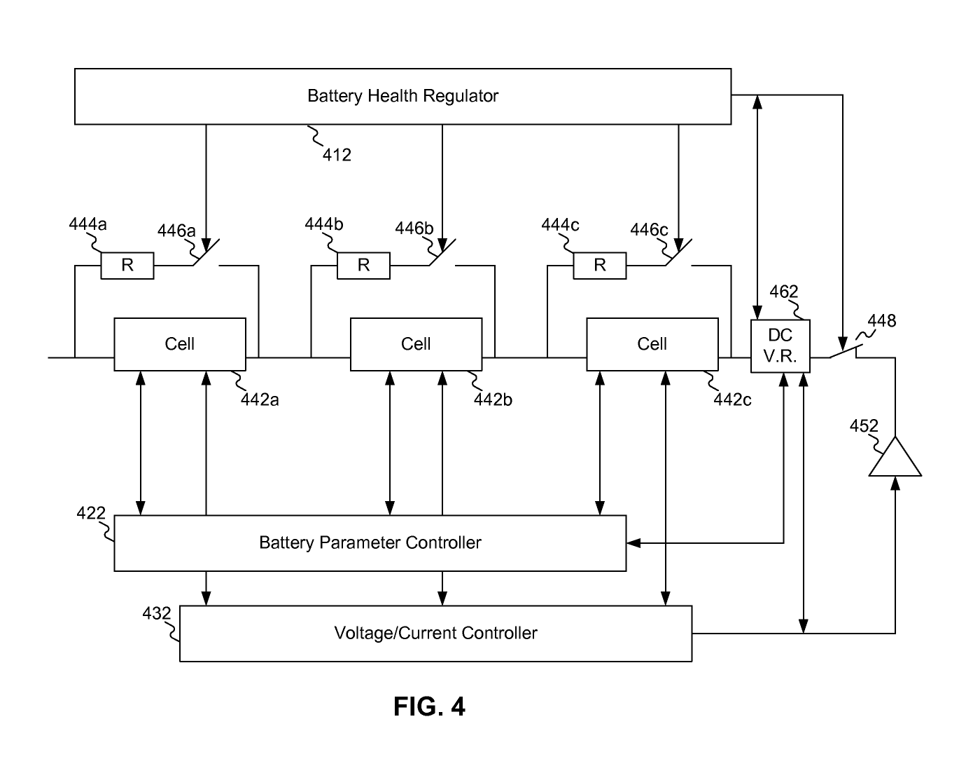

FIG. 4 is a schematic diagram of some exemplary controlling units of a smart battery controller, in accordance with some disclosed embodiments. In FIG. 4, battery health regulator 412, battery parameter controller 422, and voltage/current controller 432 are exemplary controlling units (e.g., 232-236 in FIG. 2). Referring to FIG. 4, three cells 442a, 442b, and 442c are connected in series. Each cell may have a protection circuit to protect the cell from over charging. For example, the protection circuit for cells 442a, 442b, and 442c may include switch 448 to turn off the entire charging circuit. Switch 448 may use a MOSFET. The protection circuit for cell 442a may include a resistor 444a and a switch 446a. Similarly, the protection circuit for cell 442b may include a resistor 444b and a switch 446b, and the protection circuit for cell 442c may include a resistor 444c and a switch 446c. In some embodiments, switches 446a-446c are MOSFETs. The series-connected cells may be charged by a voltage source 452. A switch 448 may be connected between voltage source 452 and the cells to turn on/off the entire charging circuit. Battery health regulator 412 may control switches 446a-446c to discharge individual cells when certain triggering conditions or events occur. For example, the triggering conditions may include over-/low-voltage, over-/low-current, over-/low-charge, over-/low-impedance, over-heat, etc. When one or more such triggering conditions occur, battery health regulator 412 may turn on the switch (e.g., switch 446a) associated with the disfunctioning cell (e.g., cell 442a) to discharge the cell such that the energy stored in cell 442a, if any, dissipates on resistor 444a. In some embodiments, battery health regulator 412 may control the discharging time based on cell status information and turn off the discharging switch when the condition of the cell improves. In some embodiments, battery health regulator 412 may choose to turn off certain cell to essentially remove the disfunctioning cell from the main battery circuit.

Battery health regulator 412 may also turn off switch 448 to shut down the entire charging circuit of the battery under certain circumstances. For example, if only one cell is disfunctioning, battery health regulator 412 may discharge that one cell by turn on the corresponding discharging switch, or battery health regulator 412 may instead shut down the entire charge circuit by turning off switch 448 to protect the battery from further damages.

Battery parameter controller 422 may control various parameters associated with the battery and/or its individual cells. For example, each cell may have one or more thresholds associated with its voltage, current, impedance, charge, charging rate, temperature, etc. These thresholds may be used to trigger one or more controlling events. For example, if the measured voltage of cell 442a is higher than a first threshold but below a second threshold, battery health regulator 412 may turn on switch 446a to discharge cell 442a. If the voltage of cell 442a is higher than the second threshold, then battery health regulator 412 may turn off switch 448 to shut down the entire charging circuit. The first and second thresholds of cell 442a may be set and/or changed by battery parameter controller 422, or may be directed from the cloud. Similarly, other thresholds and thresholds associated with other cells can also be set and/or changed by battery parameter controller 422. Battery Health Regulation, Battery Parameter Control, and Voltage/Current Control may all be in the same device, such as, on the same PCB that is attached to the battery pack, or may be in separate devices.

Voltage/current controller 432 may control the voltage applied to and/or the current flowing through one or more cells. For example, based on battery status obtained by one or more monitoring units or certain predetermined control scheme, processor 212 may instruct voltage/current controller 432 to increase or decrease the voltage applied to one or more cells. Similarly, voltage/current controller 432 may control the current (e.g., charging current or discharging current) flowing through one or more cells based on battery status obtained by one or more monitoring units or certain predetermined control scheme either through some mechanism on the battery, or indirectly through communications with a charger or a battery-connected device. Voltage/current controller 432 may also control voltage source 452 to increase or decrease overall charging voltage and/or current.

A DC voltage regulator 462 may be included in the main cell circuit to regulate DC voltage. DC voltage regulator 462 may be configured to change the DC voltage output from the battery pack. DC voltage regulator 462 may be controlled by battery health regulator 412, battery parameter controller 422, and/or voltage/current controller 432.

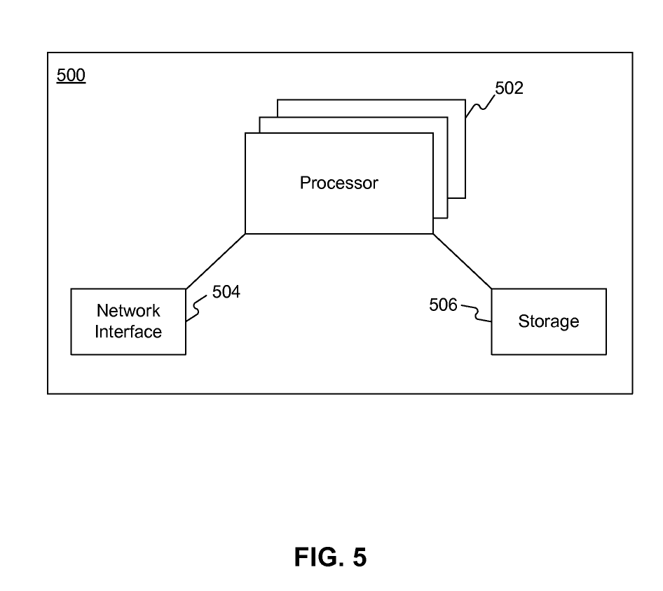

FIG. 5 is a schematic diagram of an exemplary server of a smart battery system, in accordance with some disclosed embodiments. In FIG. 5, server 500 is an exemplary implementation of server 132. Server 500 may include one or more processors 502. The one or more processors 502 may include one or more CPU, GPU, DSP, FPGA, and/or other suitable information processing devices.

Server 500 may include a network interface 504 communicatively connected with the one or more processors 502. Network interface 504 may provide wired or wireless communication connections to network 120. For example, network interface 504 may include Fiber, Ethernet, WiFi, Bluetooth, NFC, telecommunication connection (3G, 4G, LTE, etc.), or other suitable communication devices. Network interface 504 may provide network connection using TCP/IP, HTTP, HTTPS, UDP, or other suitable protocols. In some embodiments, an application programming interface (API) may be provided to facilitate communication between controller 114 and server 500.

Server 500 may include a storage device 506. Storage device 506 may include one or more magnetic storage media such as hard drive disks; one or more optical storage media such as computer disks (CDs), CD-Rs, CD±RWs, DVDs, DVD±Rs, DVD±RWs, HD-DVDs, Blu-ray DVDs; one or more semiconductor storage media such as flash drives, SD cards, memory sticks; or any other suitable computer readable media. Storage device 506 may store information received from controller 114, such as data relating to the status of battery 110, into the storage space of storage device 506.

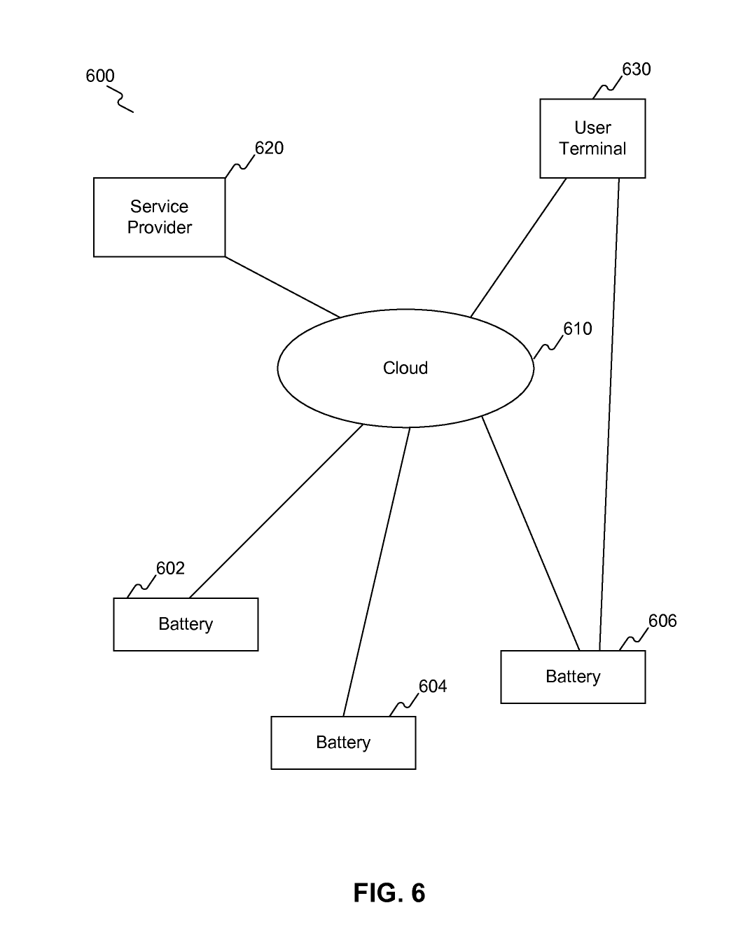

FIG. 6 is an exemplary configuration of a smart battery cloud 600, in accordance with some disclosed embodiments. In FIG. 6, a cloud 610 may include one or more servers to form a network-based computational environment. A plurality of batteries, such as batteries 602, 604, and 606, may connect to cloud 610 via network connections. Batteries 602, 604, and 606 may reside at different locations. For example, battery 602 may be located in Hawaii, battery 604 may be located in Alaska, and battery 606 may be located in Washington, D.C. The batteries may be similar or may be different. For example, batteries 602 and 604 may be similar to each other, but battery 606 may be different from both batteries 602 and 604. Cloud 610 may receive status reports from batteries 602, 604, and 606 through, for example, communicating with their respective controllers. The status reports may include information regarding, for example, voltage/current readings, charging rate, temperature, GPS location, etc. Cloud 610 may process the information contained in the reports and use the information in various ways. For example, cloud 610 may build databases based on the information. The databases may include data of a plurality of batteries. Statistical analysis can be made to generate benchmarks, guidelines, thresholds, or other important indicators for determining the healthy status of a particular battery and/or to control one or more aspects of a particular battery. For example, cloud 610 may contain data of a healthy battery similar to batteries 602 and 604. The data may be obtained from an experiment carried out in California. Based on the GPS information, cloud 610 may be aware of the locations of batteries 602 (e.g., Hawaii) and 604 (e.g., Alaska). Because of the difference in location, the healthy standard based on the battery in California may be adjusted in view of the latitude, temperature, humidity differences. In another example, if battery 606 reports any abnormal data to cloud 610, such as over-heat or over-charging, cloud 610 may issue instructions to the controller of battery 606 to intervene the charging process, for example, to either balance the load of different cells or to shut down the battery to prevent further damages.

One or more user terminals, such as user terminal 630, may be connected to cloud 610 or connected directly to one or more batteries, such as battery 606. User terminal 630 may include smart phones, tablets, computers, PDAs, dedicated devices, etc. User terminal 630 may communicate with cloud 610 or battery 606 to obtain status information of one or more batteries. Such information may be displayed to a user in numerical, textual, or graphical forms. The user may also control one or more aspects of one or more batteries, either through cloud 610 or through direct connection with the batteries, subject to certain permissions imposed by cloud 610 or battery 606. Authorization process may be implemented to grant or deny the permissions.

One or more service providers, such as service provider 620, may connect to cloud 610 to provide various services. For example, a financial institute may provide financial services such as bank transaction, credit card payment, etc. when cloud 610 involves services requiring financial transactions. In another example, a battery maintenance company may schedule battery maintenance field trips after receiving warning alarms from cloud 610. As such, unnecessary periodic visits can be avoided to reduce cost. In yet another example, a battery manufacturer may inspect battery status records to determine whether warranty claims should be honored. For example, if the data obtained by accelerometer 306 indicates that the battery was dropped, the warranty claim may be denied.

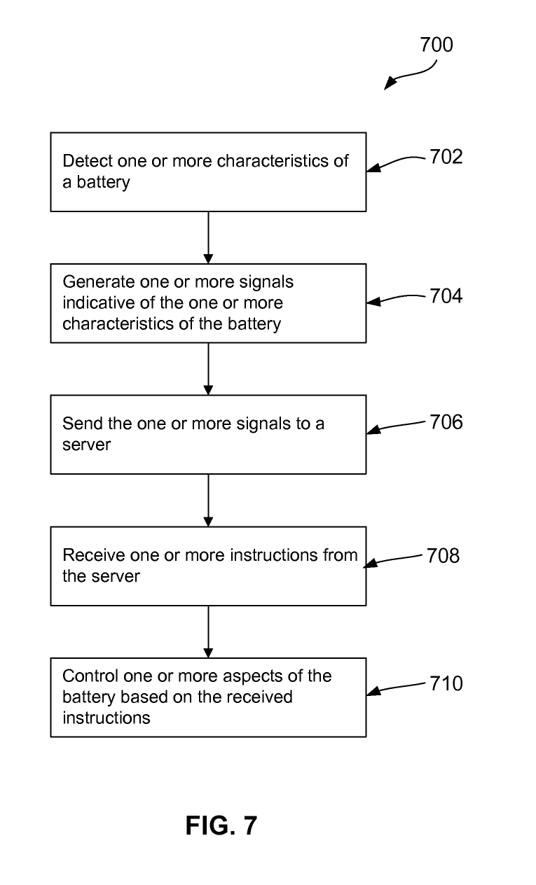

FIG. 7 is a flow chart of an exemplary method for performing smart battery management, in accordance with some disclosed embodiments. In FIG. 7, a battery management method 700 includes a series of steps, some of them may be optional. In step 702, one or more characteristics of the battery may be detected by one or more sensors. For example, accelerometer 306 may detect the acceleration of the battery, hygrometer 310 may detect the humidity of the battery, GPS 312 may detect the geographical location of the battery, thermocoupler 308 may detect the temperature of the battery, gas sensor 314 may detect the level the CO and/or CO₂ gas, etc. In step 704, one or more signals may be generated by the sensors, each signal indicating a corresponding characteristic of the battery detected by the corresponding sensor. In step 706, the one or more signals may be sent to a server (e.g., server 132) through a network (e.g., network 120). For example, the signals may be sent to the server using network interface 216. In step 708, one or more instructions may be received from the server. In step 710, one or more aspects of the battery may be controlled based on the received instructions.

As discussed above, the aspects of the battery to be controlled include directly interfering with the operation of the battery, such as turn off (e.g., disconnect) the battery, reduce charging/discharging voltage or current, etc. The system may control a battery pack as a whole or control individual battery cells. For example, if it is detected that an individual battery cell is overcharged, the system may turn on a bleeding circuit coupled to that individual battery cell to bleed off certain charges.

The aspects of the battery to be controlled may also include setting up thresholds for batteries. Based on one or more sensed values, the system may set up certain thresholds for the battery correspondingly. For example, charging and discharging voltage or current thresholds may be set up based on sensed ambient temperature. If the sensed ambient temperature is high, a lower charging threshold (maximum voltage to be charged) can be set. When the battery voltage reaches that maximum voltage, the system may stop charging the battery. For another example, the CO level threshold can also be set based on the sensed ambient temperature. If the ambient temperature is high, for safety reasons, the system may set a lower CO threshold. If the CO level in the battery reaches the threshold, the system may turn off the battery. For another example, the system may set up an upper temperature threshold based on the location of the battery. In other words, different temperature thresholds may be set up for batteries at different locations.

In the foregoing description of exemplary embodiments, various features are grouped together in a single embodiment for purposes of streamlining the disclosure. This method of disclosure is not to be interpreted as reflecting an intention that the claims require more features than are expressly recited in each claim. Rather, as the following claims reflect, inventive aspects lie in less than all features of a single foregoing disclosed embodiment. Thus, the following claims are hereby incorporated into this description of the exemplary embodiments, with each claim standing on its own as a separate embodiment of the invention.

Moreover, it will be apparent to those skilled in the art from consideration of the specification and practice of the present disclosure that various modifications and variations can be made to the disclosed systems and methods without departing from the scope of the disclosure, as claimed. Thus, it is intended that the specification and examples be considered as exemplary only, with a true scope of the present disclosure being indicated by the following claims and their equivalents.

What is claimed is:

1. A battery management device, comprising:
a sensor configured to detect a characteristic of a battery;
a processor communicatively connected with the sensor to receive a signal indicative of the characteristic of the battery;
a network interface to send the signal to a server through a network and to receive an instruction from the server through the network; and
a control circuit to control one or more aspects of the battery based on the received instruction.

2. The battery monitoring device of claim 1, wherein the sensor includes an accelerometer.

3. The battery monitoring device of claim 1, wherein the sensor includes a hygrometer.

4. The battery monitoring device of claim 1, wherein the sensor includes a thermocoupler.

5. The battery monitoring device of claim 1, wherein the sensor includes a GPS receiver.

6. The battery monitoring device of claim 1, wherein the sensor includes a gas sensor.

7. The battery monitoring device of claim 1, wherein the sensor includes a voltage sensor.

8. The battery monitoring device of claim 1, wherein the sensor includes a current sensor.

9. The battery monitoring device of claim 1, wherein the sensor includes an impedance sensor.

10. The battery monitoring device of claim 1, wherein the sensor includes a strain sensor.

11. The battery monitoring device of claim 1, wherein the sensor includes a pressure sensor.

12. The battery monitoring device of claim 1, wherein the sensor includes a dimensional sensor.

13. A battery management system, comprising:
a battery; and
a controller, wherein the controller comprises:
a sensor configured to detect a characteristic of a battery;
a processor communicatively connected with the sensor to receive a signal indicative of the characteristic of the battery;
a network interface to send the signal to a server through a network and to receive an instruction from the server through the network; and
a control circuit to control one or more aspects of the battery based on the received instruction.

14. A method for managing a battery, comprising:
detecting a characteristic of the battery;
generating a signal indicative of the characteristic of the battery; and
sending the signal to a server through a network;
receiving an instruction from the server through the network; and
controlling one or more aspects of the battery based on the received instruction.

15. The method of claim 14, wherein the characteristic includes a temperature of the battery, and controlling the one or more aspects includes setting a charging or discharging voltage threshold of the battery.

16. The method of claim 14, wherein the characteristic includes a gas level inside the battery, and controlling the one or more aspects includes disconnecting the battery from an electrical circuit.

17. The method of claim 14, wherein the characteristic includes a pressure level inside the battery, and controlling the one or more aspects includes disconnecting the battery from an electrical circuit.

18. The method of claim 14, wherein the characteristic includes location information of the battery, and controlling the one or more aspects includes setting a charging or discharging voltage threshold of the battery.

19. The method of claim 14, wherein the characteristic includes an impedance value of the battery, and controlling the one or more aspects includes setting a charging or discharging current threshold of the battery.
